(19) United States
(12) Patent Application Publication
(10) Pub. No.: US 2018/0152101 A1
(43) Pub. Date: May 31, 2018

(54) CHARGE PUMP OUTPUT POWER THROTTLING

(71) Applicant: Cirrus Logic International Semiconductor Ltd., Edinburgh (GB)

(72) Inventors: Eric J. KING, Austin, TX (US); Siddharth MARU, Austin, TX (US)

(73) Assignee: Cirrus Logic International Semiconductor Ltd., Edinburgh (GB)

(21) Appl. No.: 15/823,140

(22) Filed: Nov. 27, 2017

Related U.S. Application Data
(60) Provisional application No. 62/428,096, filed on Nov. 30, 2016.

(51) Int. Cl. H02M 3/07; H03F 3/00; H01L 27/02; G05F 3/24; H04R 3/00

(52) U.S. Cl. CPC H02M 3/07; H03F 3/005; H02M 2003/072; G05F 3/247; H04R 3/007; H01L 27/0222

(57) ABSTRACT

A system may include a charge pump configured to boost an input voltage of the charge pump to an output voltage greater than the input voltage and a controller configured to control an output power of the charge pump to ensure that an input current of the charge pump is maintained below a current limit.

### CROSS-REFERENCES AND RELATED APPLICATION

The present disclosure claims benefit of U.S. Provisional Patent Application Ser. No. 62/428,096, filed Nov. 30, 2016, which is incorporated by reference herein in its entirety.

### FIELD OF DISCLOSURE

The present disclosure relates in general to charge pump power supplies, including without limitation personal audio devices such as wireless telephones and media players, and more specifically, to systems and methods for throttling output power generated by a charge pump in order to maintain an input current limit to the charge pump.

### BACKGROUND

Personal audio devices, including wireless telephones, such as mobile/cellular telephones, cordless telephones, mp3 players, and other consumer audio devices, are in widespread use. Such personal audio devices may include circuitry for driving a pair of headphones or one or more speakers. Such circuitry often includes a power amplifier for driving an audio output signal to headphones or speakers, and the power amplifier may often be the primary consumer of power in a personal audio device, and thus, may have the greatest effect on the battery life of the personal audio device. In devices having a linear power amplifier for the output stage, power is wasted during low signal level outputs, because the voltage drop across the active output transistor plus the output voltage will be equal to the constant power supply rail voltage. Therefore, amplifier topologies such as Class-G and Class-H are desirable for reducing the voltage drop across the output transistor(s) and thereby reducing the power wasted in dissipation by the output transistor(s).

In order to provide a variable power supply voltage to such a power amplifier, a charge pump power supply may be used, for example such as that disclosed in U.S. Pat. No. 8,311,243, in which an indication of the signal level at the output of the circuit is used to control the power supply voltage in a Class-G topology. The above-described topology may raise the efficiency of the audio amplifier, in general, as long as periods of low signal level are present in the audio source. Typically in such topologies, a plurality of thresholds define output signal level-dependent operating modes for the charge pump power supply, wherein a different supply voltage is generated by the charge pump power supply in each mode.

In a typical charge pump power supply, a charge pump may operate in accordance with two non-overlapping clock phases of a switching cycle of the charge pump, with different combinations of connections among an input power source to the charge pump (e.g., a battery), a flying capacitor of the charge pump for storing charge, and an output load capacitor which provides the power supply voltage generated by the charge pump. However, one disadvantage of a charge pump may occur when switching between output voltage modes of the charge pump. In general, the voltage on the flying capacitor of the charge pump may be equal to the voltage of the input power source. If the output voltage is smaller than the sum of the input power source voltage and the flying capacitor voltage during an increase in charge pump ratio, the charge pump may need to source a large inrush current from its power source (e.g., a battery). On the other hand, if the output voltage is greater than the sum of the input power source voltage and the flying capacitor voltage, the charge pump may need to sink large current to its power source. Because of the sizes of capacitors often used in charge pumps, the amount of current that a charge pump may source or sink when switching between modes may not be able to be absorbed by the power source to the charge pump, which may lead to system damage. Accordingly, methods and systems for limiting such switching currents are desirable.

In a non-current limited system, a boost stage pulls as much energy from its input as is required by the output load. As the power required by the output stage increases, the input current also increases. This input current is highest during maximum output power delivery. If this input current is limited with a view to limiting the output power, all the energy needed by the output stage cannot be pulled by the boost stage. The difference between the energy required by the output stage and that provided by the boost stage is supplied by the intermediate storage capacitor. This manner of energy supply leads to the capacitor getting discharged and the intermediate voltage dropping.

In an inductor-based conventional boost stage, the drop in capacitor voltage does not degrade the efficiency of the boost stage. However, in a charge pump based boost stage, the efficiency degrades as the boost output voltage drops. The further the charge pump output voltage is from a product of an input battery voltage times a multiplication ratio of the charge pump, the less efficient it is. A reduction in efficiency may in turn cause less energy to be pushed by the charge pump onto the intermediate capacitor, thus exacerbating the problem.

Thus, in a charge pump-based boost, limiting the input current does not just limit the output power (as in an inductor-based boost) but also degrades the system efficiency. This inefficiency causes less than the intended power to be generated at the output.

Directly throttling the power pushed to the output would be one way of preventing the intermediate capacitor from discharging significantly and hence improving charge pump efficiency. Throttling the output power can lead to very high charge pump efficiency but cause very little power to get pushed to the output. Excessive throttling may also needlessly bring the system out of the current limit due to excessive reduction in input power. Consequently, a way of optimally throttling the output power is needed or desired so as to keep the charge pump efficiency high while pushing as much power as possible to the output (e.g., keeping the input current close to but slightly lower than the limit). Output power throttling combined with input current limiting would help in maintaining high system efficiency and transferring maximum possible power to the load at the given input current limit.

### SUMMARY

In accordance with the teachings of the present disclosure, certain disadvantages and problems associated with performance of charge pumps have been reduced or eliminated.

In accordance with embodiments of the present disclosure, a system may include a charge pump configured to boost an input voltage of the charge pump to an output voltage greater than the input voltage and a controller configured to control an output power of the charge pump to ensure that an input current of the charge pump is maintained below a current limit.

In accordance with these and other embodiments of the present disclosure, a method may comprise controlling an output power of a charge pump to ensure that an input current of the charge pump is maintained below a current limit, wherein the charge pump is configured to boost an input voltage of the charge pump to an output voltage greater than the input voltage.

In accordance with these and other embodiments of the present disclosure, a controller may include an input for receiving an input signal indicative of an input current of the charge pump configured to boost an input voltage of the charge pump to an output voltage greater than the input voltage and logic configured to generate one or more control signals for controlling an output power of the charge pump to ensure that the input current is maintained below a current limit.

Technical advantages of the present disclosure may be readily apparent to one having ordinary skill in the art from the figures, description and claims included herein. The objects and advantages of the embodiments will be realized and achieved at least by the elements, features, and combinations particularly pointed out in the claims.

It is to be understood that both the foregoing general description and the following detailed description are explanatory examples and are not restrictive of the claims set forth in this disclosure.

### BRIEF DESCRIPTION OF THE DRAWINGS

A more complete understanding of the example, present embodiments and certain advantages thereof may be acquired by referring to the following description taken in conjunction with the accompanying drawings, in which like reference numbers indicate like features, and wherein:

FIG. 1 is an illustration of an example personal audio device, in accordance with embodiments of the present disclosure;

FIG. 2 is a block diagram of selected components of an example integrated circuit, which may be implemented as an audio integrated circuit of the personal audio device depicted in FIG. 1 or any other suitable device, in accordance with embodiments of the present disclosure;

FIG. 3 is a block diagram of selected components of an example charge pump power supply, in accordance with embodiments of the present disclosure;

FIG. 4 is a block diagram of selected components of an example control circuit, in accordance with embodiments of the present disclosure; and

FIG. 5 is a block diagram of selected components of another example control circuit, in accordance with embodiments of the present disclosure.

### DETAILED DESCRIPTION

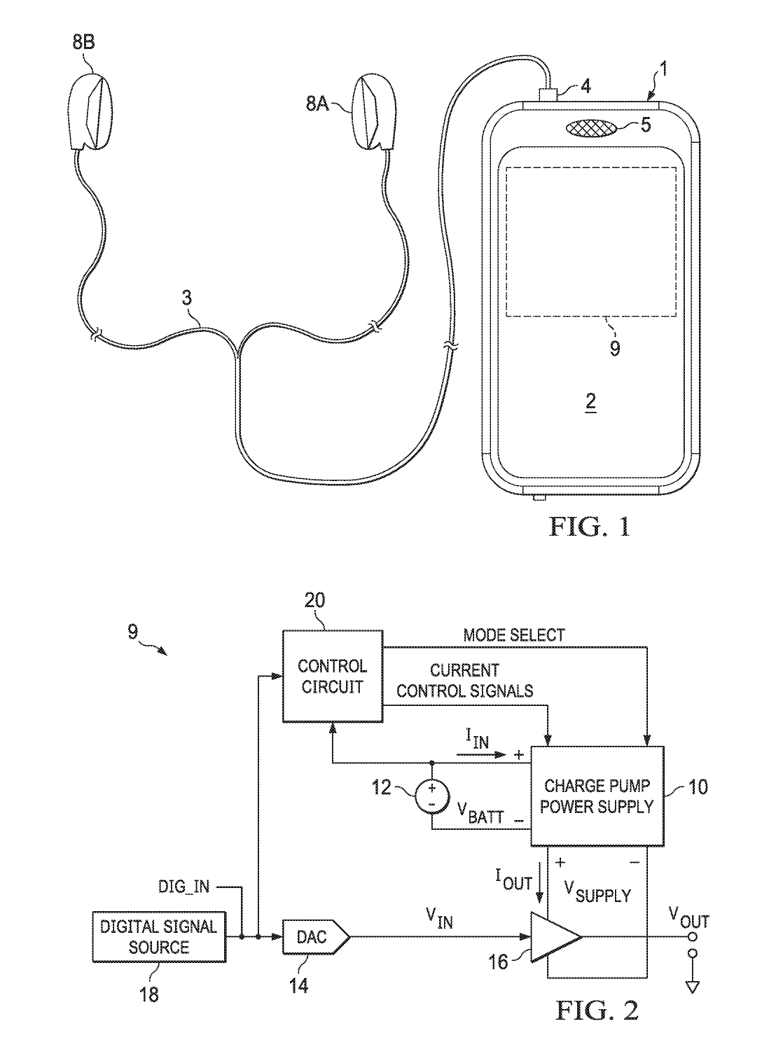

FIG. 1 is an illustration of an example personal audio device 1, in accordance with embodiments of the present disclosure. Personal audio device 1 is an example of a device in which techniques in accordance with embodiments of the present disclosure may be employed, but it is understood that not all of the elements or configurations embodied in illustrated personal audio device 1, or in the circuits depicted in subsequent illustrations, are required in order to practice the subject matter recited in the claims. Personal audio device 1 may include a transducer such as speaker 5 that reproduces distant speech received by personal audio device 1, along with other local audio events such as ringtones, stored audio program material, injection of near-end speech (i.e., the speech of the user of personal audio device 1) to provide a balanced conversational perception, and other audio that requires reproduction by personal audio device 1, such as sources from webpages or other network communications received by personal audio device 1 and audio indications such as a low battery indication and other system event notifications. In addition or alternatively, a headset 3 may be coupled to personal audio device 1 for generating audio. As shown in FIG. 1, a headset 3 may be in the form of a pair of earbud speakers 8A and 8B. A plug 4 may provide for connection of headset 3 to an electrical terminal of personal audio device 1. Headset 3 and speaker 5 depicted in FIG. 1 are merely examples, and it is understood that personal audio device 1 may be used in connection with a variety of audio transducers, including without limitation, captive or integrated speakers, headphones, earbuds, in-ear earphones, and external speakers.

Personal audio device 1 may provide a display to a user and receive user input using a touch screen 2, or alternatively, a standard LCD may be combined with various buttons, sliders, and/or dials disposed on the face and/or sides of personal audio device 1.

As also shown in FIG. 1, personal audio device 1 may include an audio integrated circuit (IC) 9 for generating an analog audio signal for transmission to headset 3, speaker 5, and/or another audio transducer.

FIG. 2 is a block diagram of selected components of an example IC 9, which may be implemented as audio IC 9 of personal audio device 1 or any other suitable device, in accordance with embodiments of the present disclosure. As shown in FIG. 2, a digital signal source 18 (e.g., a processor, digital signal processor, microcontroller, test equipment, or other suitable digital signal source) may supply a digital input signal DIG_IN to a digital-to-analog converter (DAC) 14, which may in turn convert digital input signal DIG_IN into an equivalent analog input signal V_{IN} and communicate analog input signal V_{IN} to a power amplifier stage 16 which may amplify or attenuate the analog input signal V_{IN} and provide an output signal V_{OUT}, which, in embodiments in which digital input signal DIG_IN, analog input signal V_{IN}, and output signal V_{OUT} are audio signals, may operate a speaker, headphone transducer, and/or a line level signal output. However, application of IC 9 as depicted in FIG. 2 may not be limited to audio applications. In addition, although amplifier stage 16 is depicted as a single-ended output generating a single-ended audio output signal V_{OUT}, in some embodiments, amplifier stage 16 may comprise a differential output, and may thus provide a differential audio output signal V_{OUT}.

A charge pump power supply 10 may provide the power supply rail inputs of a supply voltage V_{SUPPLY} to amplifier 16 and may receive a power source input, generally from a battery 12 or other power supply, which may provide an input voltage V_{BATT} to charge pump power supply 10. A control circuit 20 may supply a mode select signal to charge pump power supply 10 that selects an operating mode of charge pump power supply 10 so as to adjust supply voltage V_{SUPPLY} generated by charge pump power supply 10 according to expected and/or actual signal levels at the output of amplifier 16. When low signal levels exist and/or are expected at amplifier output V_{OUT}, mode control circuit 20 may improve the power efficiency of audio IC 9 by varying the supply voltage V_{SUPPLY} in conformity with the output signal V_{OUT} or a signal (e.g., digital input signal DIG_IN) indicative of the output signal V_{OUT}. Accordingly, to maintain power efficiency, at any given time control circuit 20 may select an operating mode from a plurality of operating modes in each operating mode operating charge pump power supply 10 at a different supply voltage, V_{SUPPLY}, wherein the supply voltage V_{SUPPLY} in one operational mode is a rational multiple or ratio of supply voltages of other operational modes.

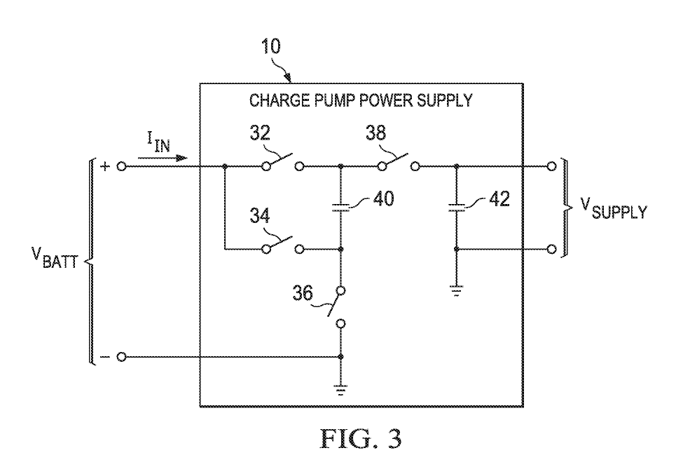

FIG. 3 is a block diagram of selected components of an example charge pump power supply 10, in accordance with embodiments of the present disclosure. Charge pump power supply 10 as shown in FIG. 3 may be configured to operate in two modes: a first mode in which the supply voltage V_{SUPPLY} output by charge pump power supply 10 is equal to input voltage V_{BATT}, and a second mode in which the supply voltage V_{SUPPLY} output by charge pump power supply 10 is equal to two times input voltage V_{BATT}. As shown in FIG. 3, charge pump power supply 10 may include switches 32, 34, 36, and 38, a flying capacitor 40, and a charge pump output capacitor 42.

Each switch 32, 34, 36, and 38 may comprise any suitable device, system, or apparatus for making a connection in an electric circuit when the switch is enabled (e.g., closed or on) and breaking the connection when the switch is disabled (e.g., open or off) in response to a control signal received by the switch. For purposes of clarity and exposition, control signals for switches 32, 34, 36, and 38 are not depicted, although such control signals would be present to selectively enable and disable switches 32, 34, 36, and 38. In some embodiments, a switch 32, 34, 36, and 38 may comprise an n-type metal-oxide-semiconductor field-effect transistor. In these and other embodiments, a switch 32, 34, 36, and 38 may comprise a p-type metal-oxide-semiconductor field-effect transistor. Switch 32 may be coupled between a positive input terminal of charge pump power supply 10 and a first terminal of flying capacitor 40. Switch 34 may be coupled between the positive input terminal of charge pump power supply 10 and a second terminal of flying capacitor 40. Switch 36 may be coupled between a negative input terminal of charge pump power supply 10 and a second terminal of flying capacitor 40. Switch 38 may be coupled between the first terminal of flying capacitor 40 and a first terminal of charge pump output capacitor 42.

Flying capacitor 40 and charge pump output capacitor 42 may each comprise a passive two-terminal electrical component used to store energy electrostatically in an electric field, which may generate a current in response to a time-varying voltage across the capacitor (or vice versa). Charge pump output capacitor 42 may be coupled between the output terminals of charge pump power supply 10, and thus may store supply voltage V_{SUPPLY} output by charge pump power supply 10.

In the first mode, charge pump power supply 10 may operate in a single phase, wherein switch 34 may be disabled and switches 32, 36, and 38 may be enabled during operation, thus charging voltage V_{SUPPLY} on charge pump output capacitor 42 to input voltage V_{BATT}. In the second mode, charge pump power supply 10 may sequentially operate in a charging phase in which switches 32 and 36 are enabled and switches 34 and 38 are disabled, allowing charge transfer from battery 12 to flying capacitor 40, and a transfer phase in which switches 32 and 36 are disabled and switches 34 and 38 are enabled, boosting the voltage on flying capacitor 40 and allowing charge transfer from flying capacitor 40 to charge pump output capacitor 42.

Although FIG. 3 depicts a particular implementation of a charge pump power supply 10 configured to switch between a first mode in which the boost ratio of supply voltage V_{SUPPLY} and input voltage V_{BATT} is 1, and a second mode in which the boost ratio of supply voltage V_{SUPPLY} and input voltage V_{BATT} is 2, the systems and methods herein may generally apply to charge pump power supplies having more than two modes of operation and/or boost ratios other than 1 or 2 (e.g., 1.5, 3, etc.). In addition, although FIG. 3 depicts a particular implementation of a charge pump power supply 10 having switches 32-38, a single flying capacitor 40, and a charge pump output capacitor 42, the systems and methods herein may generally apply to charge pump power supplies having any suitable topology of switches, one or more flyback capacitors, and one or more load capacitors.

As shown in FIGS. 2 and 3, battery 12 may supply a current I_{IN} to charge pump power supply 10, and charge pump power supply 10 may generate a current I_{OUT} to amplifier 16. As mentioned in the Background section of this application, it may be advantageous to limit the current I_{IN} sourced from or sunk to battery 12 by charge pump power supply 10. Thus, in accordance with methods and systems of the present disclosure, control circuit 20 may also be configured to generate control signals as shown in FIG. 2 to limit input current I_{IN}. Examples of such current limiting are set forth in U.S. patent application Ser. No. 15/783,506 filed Oct. 13, 2017 and U.S. patent application Ser. No. 15/800,743 filed Nov. 1, 2017, both of which are incorporated by reference herein. In addition, control circuit 20 may also be configured to generate control signals as shown in FIG. 2 to throttle output power, as described in greater detail below.

Thus, in operation, control circuit 20 may control an output power of charge pump power supply by controlling an output voltage generated by the charge pump. In some embodiments, control circuit 20 may the output power by controlling supply voltage V_{SUPPLY} generated by charge pump power supply 10 based on a measurement of one or more variables (e.g., input voltage V_{BATT}, supply voltage V_{SUPPLY}, and/or a multiplication ratio) associated with charge pump power supply 10.

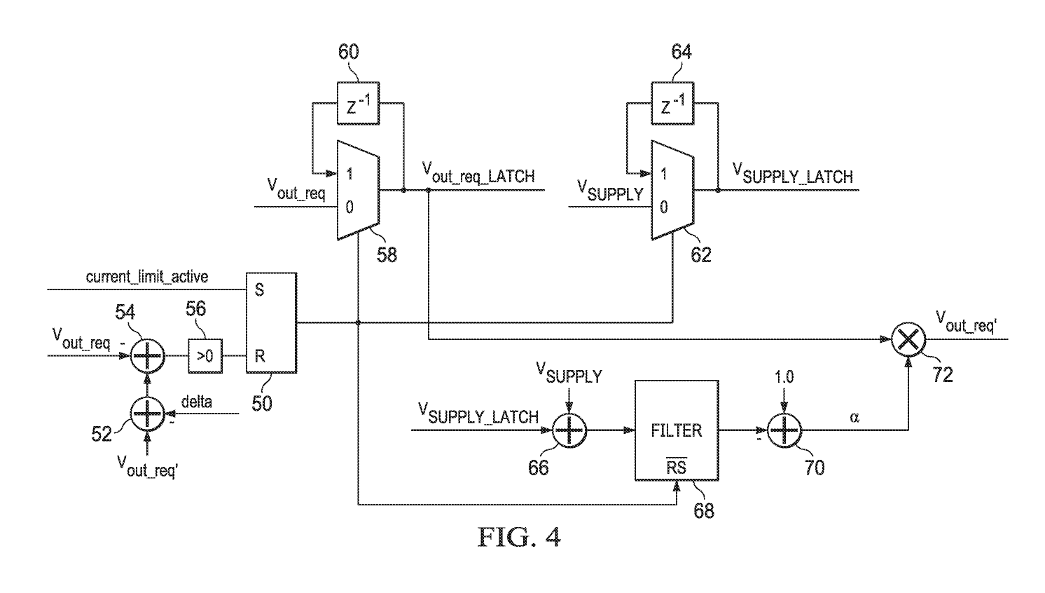

FIG. 4 is a block diagram of selected components of an example control circuit 20A, in accordance with embodiments of the present disclosure. In some embodiments, example control circuit 20A of FIG. 4 may be used to implement control circuit 20 of FIG. 2. To that end, the components of example control circuit 20A may form all or part of logic configured to carry out the functionality of control circuit 20. As shown in FIG. 4, example control circuit 20A may include an SR flip-flop 50, a combiner 52, a combiner 54, a comparator 56, a multiplexer 58, a delay element 60, a multiplexer 62, a delay element 64, a combiner 66, a filter 68, a combiner 70, and a multiplier 72, as arranged as shown in FIG. 4. Together, using these components as arranged in FIG. 4, control circuit 20A may implement a feedback servo loop to control an output power generated by charge pump power supply 10 when charge pump power supply 10 is current limited.

Thus, in operation, control circuit 20A may, upon an initial indication of an active current limit being applied to input current I_{IN} (as indicated by signal CURRENT_LIMIT_ACTIVE shown in FIG. 4), latch a requested output voltage V_{OUT}_{_}_{REQ} requested by amplifier 16 to generate a latched requested output voltage V_{OUT}_{_}_{REQ}_{_}_{LATCH}. In addition, control circuit 20A may, upon the initial indication of the active current limit being applied to input current I_{IN} (as indicated by signal CURRENT_LIMIT_ACTIVE shown in FIG. 4), latch a supply voltage V_{SUPPLY} output charge pump power supply 10 to generate a latched supply voltage V_{SUPPLY}_{_}_{LATCH}.

Further, control circuit 20A may generate a scaling factor α as a function of a filtered difference between supply voltage V_{SUPPLY} and latched supply voltage V_{SUPPLY}_{_}_{LATCH}. To implement such filtering, filter 68 may comprise any suitable filter, including a proportional-integral filter. Control circuit 20A may multiply such scaling factor α by latched requested output voltage V_{OUT}_{_}_{REQ}_{_}_{LATCH} to generate a scaled requested output voltage V_{OUT}_{_}_{REQ}′ requested by amplifier 16. Thus, control circuit 20A may control output power generated by charge pump power supply 10 responsive to initiation of input current limiting by controlling an output voltage generated by charge pump power supply 10 in a feedback, servoed manner.

Control circuit 20A may cease output power control and return to normal operation at a point in time in which the requested output voltage V_{OUT}_{_}_{REQ} requested by amplifier 16 has fallen below the servoed scaled requested output voltage V_{OUT}_{_}_{REQ}′ by a threshold level DELTA.

Thus, in accordance with the above, control circuit 20A may be configured to control the output power of charge pump power supply 10 by controlling its output voltage V_{SUPPLY} such that the voltage V_{SUPPLY} is gradually reduced in a series of steps based on a pre-determined attenuation (e.g., scaling factor α) of voltage V_{SUPPLY} at the time power control is instantiated. In addition, control circuit 20A may gradually reduce voltage V_{SUPPLY} and cause charge pump power supply 10 to remain in an input current limited state until such time as a requested output voltage (requested output voltage V_{OUT}_{_}_{REQ}) of charge pump power supply 10 falls below a threshold voltage (e.g., scaled requested output voltage V_{OUT}_{_}_{REQ}′ reduced by threshold level DELTA).

Although FIG. 4 depicts a particular embodiment of a feedback servo loop for power control, control circuit 20 shown in FIG. 2 may be implemented using any suitable arrangement of components with structure and/or functionality similar to that described above.

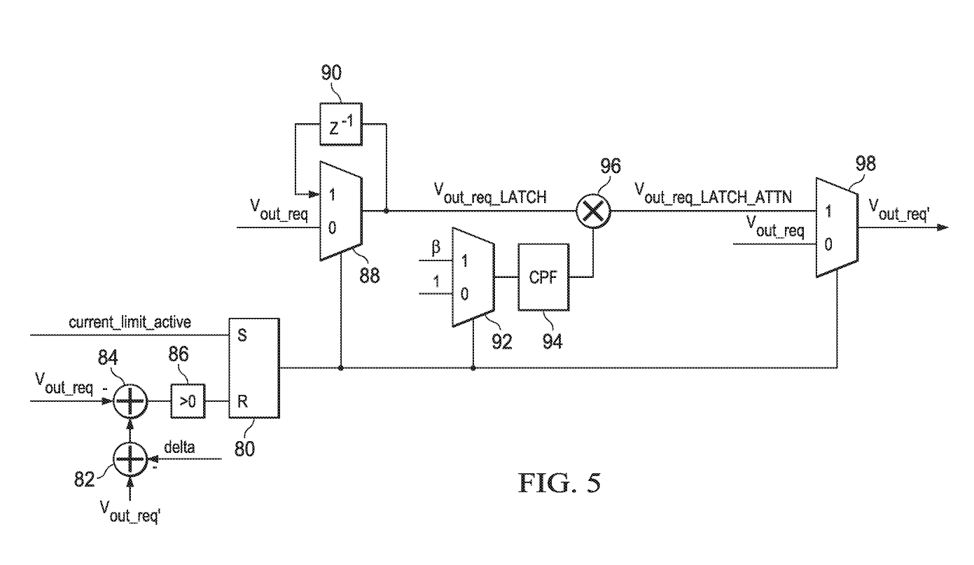

FIG. 5 is a block diagram of selected components of an example control circuit 20B, in accordance with embodiments of the present disclosure. In some embodiments, example control circuit 20B of FIG. 5 may be used to implement control circuit 20 of FIG. 2. To that end, the components of example control circuit 20B may form all or part of logic configured to carry out the functionality of control circuit 20. As shown in FIG. 5, example control circuit 20B may include an SR flip-flop 80, a combiner 82, a combiner 84, a comparator 86, a multiplexer 88, a delay element 90, a multiplexer 92, a low-pass filter 94, a multiplier 96, and a multiplexer 98, as arranged as shown in FIG. 5. Together, using these components as arranged in FIG. 5, control circuit 20B may implement a feedforward control to control an output power generated by charge pump power supply 10 when charge pump power supply 10 is current limited.

Thus, in operation, control circuit 20B may, upon an initial indication of an active current limit being applied to input current I_{IN} (as indicated by signal CURRENT_LIMIT_ACTIVE shown in FIG. 5), latch a requested output voltage V_{OUT}_{_}_{REQ} requested by amplifier 16 to generate a latched requested output voltage V_{OUT}_{_}_{REQ}_{_}_{LATCH}. In addition, control circuit 20B may, upon an initial indication of an active current limit being applied to input current I_{IN} (as indicated by signal CURRENT_LIMIT_ACTIVE shown in FIG. 5), modify a gain factor from a unity gain of 1 to a gain 13 less than 1, filter such gain factor with low-pass filter 94, and multiply such filtered gain factor by the latched requested output voltage V_{OUT}_{_}_{REQ}_{_}_{LATCH} to generate attenuated latched requested output voltage V_{OUT}_{_}_{REQ}_{_}_{LATCH}_{_}_{ATTN}. The effect of low-pass filter 94 is to reduce the gain factor applied at multiplier 96 from 1 to gain 13 over a period of time, which may occur in a stepwise fashion.

When an active current limit is being applied to input current I_{IN} (as indicated by signal CURRENT_LIMIT_ACTIVE shown in FIG. 5), control circuit 20B may apply a modified V_{OUT}_{_}_{REQ}′ requested by amplifier 16 in lieu of requested output voltage V_{OUT}_{_}_{REQ}. Thus, control circuit 20B may control output power generated by charge pump power supply 10 responsive to initiation of input current limiting by controlling an output voltage generated by charge pump power supply 10 in a feedforward manner.

Control circuit 20B may cease output power control and return to normal operation at a point in time in which the requested output voltage V_{OUT}_{_}_{REQ} requested by amplifier 16 has fallen below the servoed scaled requested output voltage V_{OUT}_{_}_{REQ}′ by a threshold level DELTA.

Although FIG. 5 depicts a particular embodiment of a feedforward control for power control, control circuit 20 shown in FIG. 2 may be implemented using any suitable arrangement of components with structure and/or functionality similar to that described above.

This disclosure encompasses all changes, substitutions, variations, alterations, and modifications to the exemplary embodiments herein that a person having ordinary skill in the art would comprehend. Similarly, where appropriate, the appended claims encompass all changes, substitutions, variations, alterations, and modifications to the exemplary embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

All examples and conditional language recited herein are intended for pedagogical objects to aid the reader in understanding this disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

What is claimed is:

1. A system comprising:
a charge pump configured to boost an input voltage of the charge pump to an output voltage greater than the input voltage; and
a controller configured to control an output power of the charge pump to ensure that an input current of the charge pump is maintained below a current limit.

2. The system of claim 1, wherein the controller is configured to:
measure the input current; and
initiate power control of the output power responsive to the input current exceeding a threshold current.

3. The system of claim 2, wherein the controller is configured to control the output power by delivering an output power approximately equal to an output power level generated when the input current is approximately equal to the threshold current.

4. The system of claim 2, wherein the controller is configured to control the output power by controlling an output voltage generated by the charge pump such that the output voltage is gradually reduced in a series of steps based on a pre-determined attenuation of the output voltage at the time power control is instantiated.

5. The system of claim 4, wherein the controller is configured to gradually reduce the output voltage and cause the charge pump to remain in an input current limited state until such time as a requested output voltage of the charge pump falls below a threshold voltage.

6. The system of claim 1, wherein the controller is configured to control the output power by controlling an output voltage generated by the charge pump.

7. The system of claim 6, wherein the controller is configured to control the output power by controlling the output voltage based on a measurement of one or more variables associated with the charge pump.

8. The system of claim 7, wherein the one or more variables comprise an input voltage of the charge pump, the output voltage, and a multiplication ratio defining a desired relationship between the output voltage and the input voltage.

9. A method comprising controlling an output power of a charge pump to ensure than an input current of the charge pump is maintained below a current limit, wherein the charge pump is configured to boost an input voltage of the charge pump to an output voltage greater than the input voltage.

10. The method of claim 9, further comprising:
measuring the input current; and
initiating power control of the output power responsive to the input current exceeding a threshold current.

11. The method of claim 10, further comprising controlling the output power by delivering an output power approximately equal to an output power level generated when the input current is approximately equal to the threshold current.

12. The method claim 10, further comprising controlling the output power by controlling an output voltage generated by the charge pump such that the output voltage is gradually reduced in a series of steps based on a pre-determined attenuation of the output voltage at the time power control is instantiated.

13. The method of claim 12, further comprising gradually reducing the output voltage and causing the charge pump to remain in an input current limited state until such time as a requested output voltage of the charge pump falls below a threshold voltage.

14. The method of claim 9, further comprising controlling the output power by controlling an output voltage generated by the charge pump.

15. The method of claim 14, further comprising controlling the output power by controlling the output voltage based on a measurement of one or more variables associated with the charge pump.

16. The method of claim 15, wherein the one or more variables comprise an input voltage of the charge pump, the output voltage, and a multiplication ratio defining a desired relationship between the output voltage and the input voltage.

17. A controller comprising:
an input for receiving an input signal indicative of an input current of a charge pump configured to boost an input voltage of the charge pump to an output voltage greater than the input voltage; and
logic configured to generate one or more control signals for controlling an output power of the charge pump to ensure that the input current is maintained below a current limit.

18. The controller of claim 17, wherein the logic is further configured to:
measure the input current; and
initiate power control of the output power responsive to the input current exceeding a threshold current.

19. The controller of claim 18, wherein the logic is further configured to control the output power by delivering an output power approximately equal to an output power level generated when the input current is approximately equal to the threshold current.

20. The controller claim 18, wherein the logic is further configured to control the output power by controlling an output voltage generated by the charge pump such that the output voltage is gradually reduced in a series of steps based on a pre-determined attenuation of the output voltage at the time power control is instantiated.

21. The controller of claim 20, wherein the logic is further configured to gradually reduce the output voltage and cause the charge pump to remain in an input current limited state until such time as a requested output voltage of the charge pump falls below a threshold voltage.

22. The controller of claim 17, wherein the logic is further configured to control the output power by controlling an output voltage generated by the charge pump.

23. The controller of claim 22, wherein the logic is further configured to control the output power by controlling the output voltage based on a measurement of one or more variables associated with the charge pump.

24. The controller of claim 23, wherein the one or more variables comprise an input voltage of the charge pump, the output voltage, and a multiplication ratio defining a desired relationship between the output voltage and the input voltage.
